(19) United States
(12) Patent Application Publication
(10) Pub. No.: US 2014/0003113 A1
(43) Pub. Date: Jan. 2, 2014

(54) SEMICONDUCTOR DEVICE HAVING OPEN BITLINE STRUCTURE

(71) Applicant: ELPIDA MEMORY, INC., Tokyo (JP)

(72) Inventors: Masaki SENO, Tokyo (JP); Akiyoshi YAMAMOTO, Tokyo (JP)

(21) Appl. No.: 13/927,937

(22) Filed: Jun. 26, 2013

(30) Foreign Application Priority Data
Jun. 27, 2012 (JP) 2012-144347

(51) Int. Cl. G11C 7/18; G11C 7/10; G11C 7/06

(52) U.S. Cl. CPC G11C 7/18; G11C 7/06; G11C 7/10
USPC 365/51

(57) ABSTRACT

Disclosed herein is a semiconductor device that includes: a plurality of memory arrays disposed in a first direction and a second direction that crosses the first direction; a plurality of row decoders disposed along a first side of the memory arrays; a plurality of first column decoders each disposed along a second side that does not face the first side of an associated one of the memory arrays; and a plurality of second column decoders each disposed along a third side that faces the second side of an associated one of the memory arrays. Each of the memory arrays is sandwiched between a corresponding one of the first column decoders and a corresponding one of the second column decoders.

### BACKGROUND OF THE INVENTION

1. Field of the Invention

The present invention relates to a semiconductor device, and particularly to a semiconductor device equipped with a memory cell array having an open bitline structure.

2. Description of Related Art

In many semiconductor devices such as DRAM (Dynamic Random Access Memory), a potential difference that is appeared between bit lines paired is amplified by a sense amplifier, and data is read from a memory cell as a result. A structure of assigning a pair of bit lines to the same memory mat is called a folded bitline structure. A structure of assigning a pair of bit lines to different memory mats is called an open bitline structure. As an example of a semiconductor memory device having an open bitline structure, the semiconductor memory devices disclosed in Japanese Patent Application Laid-open No. 2002-15578 and Japanese Patent Application Laid-open No. 2011-34645 are known.

In the semiconductor memory device disclosed in Japanese Patent Application Laid-open No. 2011-34645, on an X-direction side of memory banks, row decoders are disposed; on a Y-direction side, column decoders and main amplifiers are disposed. In the case of such a layout, the maximum length of a main I/O line that is connected to a main amplifier is substantially equal to the Y-direct ion length of a memory bank. Therefore, the problem is that it is difficult to increase an access speed. To solve the problem, a memory bank may be divided into two in the Y-direction, and a column decoder and a main amplifier may be disposed between the divided memory banks. According to such a layout, the maximum length of the main I/O line is substantially reduced to one-half of the Y-direction length of the memory bank. As a result, it becomes possible to increase the access speed.

However, in a semiconductor memory device with an open bitline structure, the storage capacity of an end memory mat that is positioned in a Y-direction end portion is a half of the storage capacity of the other memory mats. Therefore, if a memory bank is divided into two in the Y-direction, the number of end mats doubles. As a result, another problem arises that the area of a chip is increased. Thus, what is desired is a semiconductor memory device that can increase the access speed while preventing an increase in the area of the chip. The same thing is required not only for semiconductor memory devices such as DRAM, but also for semiconductor devices overall that are equipped with a memory cell array having an open bitline structure.

### SUMMARY

In one embodiment, there is provided a semiconductor device that includes: a plurality of memory mats arranged in a first direction and selected based on a mat address, the plurality of memory mats including a first memory mat disposed in one end portion of the first direction, a second memory mat disposed in the other end portion of the first direction, and a third memory mat positioned between the first and second memory mats; and a plurality of sense amplifier areas each arranged between two of the memory mats that are adjacent to each other in the first direction, each of the sense amplifier areas including a plurality of sense amplifiers. Each of the memory mats includes a plurality of bit lines extending in the first direction, a plurality of word lines extending in a second direction that crosses the first direction, and a plurality of memory cells disposed at intersections of the bit lines and word lines. Each of the sense amplifiers is connected to an associated one of the bit lines included in an adjacent one of the memory mats on one side of the first direction, and to an associated one of the bit lines included in an adjacent one of the memory mats on the other side of the first direction. The first and third memory mats are selected when the mat address indicates a first value, and the second and third memory mats are selected when the mat address indicates a second value that is different from the first value.

In another embodiment, there is provided a semiconductor device that includes: a plurality of memory mats arranged in a first direction, the plurality of memory mats including a first memory mat disposed in one end portion of the first direction, a second memory mat disposed in the other end portion of the first direction, and a third memory mat positioned between the first and second memory mats; a plurality of sense amplifier areas each arranged between two of the memory mats that are adjacent to each other in the first direction, each of the sense amplifier areas including a plurality of sense amplifiers; first and second main amplifiers disposed such that the plurality of memory mats are sandwiched therebetween in the first direction; and a plurality of first and second main input/output lines provided on the plurality of memory mats and extending in the first direction. Each of the memory mats includes a plurality of bit lines extending in the first direction, a plurality of word lines extending in a second direction that crosses the first direction, and a plurality of memory cells disposed at intersections of the bit lines and word lines. Each of the sense amplifiers is connected to an associated one of the bit lines included in an adjacent one of the memory mats on one side of the first direction, and to an associated one of the bit lines included in an adjacent one of the memory mats on the other side of the first direction. The first main input/output lines connect a plurality of sense amplifiers disposed between the first and third memory mats to the first main amplifier, and the second main input/output lines connect a plurality of sense amplifiers disposed between the second and third memory mats to the second main amplifier.

In still another embodiment, there is provided a semiconductor device that includes: a plurality of memory arrays disposed in a first direction and a second direction that crosses the first direction; a plurality of row decoders disposed along a first side of the memory arrays; a plurality of first column decoders each disposed along a second side that does not face the first side of an associated one of the memory arrays; and a plurality of second column decoders each disposed along a third side that faces the second side of an associated one of the memory arrays. Each of the memory arrays is sandwiched between a corresponding one of the first column decoders and a corresponding one of the second column decoders.

According to the present invention, because two end mats are grouped into one memory mat, it becomes possible to increase the access speed while preventing an increase in the area of the chip.

### BRIEF DESCRIPTION OF THE DRAWINGS

FIG. 1 is a schematic plan view showing a layout of a semiconductor device according to a first embodiment of the present invention;

FIG. 2 is a schematic diagram for explaining a structure of a memory cell array area ARY shown in FIG. 1;

FIG. 3 is a schematic view for explaining a structure of a memory cell array area ARY that the inventors have conceived as a prototype in the course of making the present invention;

FIG. 4 is a schematic diagram for explaining how end mats MAT16a and MAT16b are combined;

FIG. 5 is a schematic plan view showing a part of the memory cell array area ARY shown in FIG. 2 in more detail in an enlarged manner;

FIG. 6 is a schematic plan view showing a part of the memory cell array area ARY shown in FIG. 5 in a further enlarged manner;

FIG. 7 is a circuit diagram indicative of an embodiment of a sense amplifier SA and equalizing circuit EQ shown in FIG. 6;

FIG. 8 is a schematic plan view indicative of one example of a relationship between a pair of local input/output lines LIOT and LIOB and a pair of main input/output lines MIOT and MIOB shown in FIG. 6;

FIG. 9 is a schematic diagram for explaining a connection relationship between main amplifiers AMP and main input/output lines MIO;

FIG. 10 is a schematic diagram for explaining a connection relationship between column decoders YDEC and column selection lines YSL;

FIG. 11 is a schematic diagram indicative of sense amplifier areas that are activated when a memory mat MAT1 shown in FIGS. 9 and 10 is selected;

FIG. 12 is a schematic diagram showing sense amplifier areas that are activated when memory mats MAT0 and MAT16 shown in FIGS. 9 and 10 are selected;

FIG. 13 is a circuit diagram indicative of an embodiment of a sense amplifier drive circuit that controls potentials of common source lines PCS and NCS shown in FIG. 7;

FIGS. 14A and 14B are waveform diagrams for explaining an operation of the sense amplifier drive circuit shown in FIG. 13;

FIG. 15 is a schematic diagram for explaining use places of overdrive potentials VOD and VODE;

FIG. 16 is a block diagram indicative of an embodiment of power supply circuits 150 and 151 that generate the overdrive potentials VOD and VODE shown in FIG. 15;

FIG. 17 is a circuit diagram indicative of an embodiment of a sense amplifier drive circuit that controls potentials of the common source lines PCS and NCS that are assigned to sense amplifier areas SAA0 and SAA31 shown in FIG. 15;

FIG. 18 is a circuit diagram indicative of an embodiment of another method of adjusting the overdrive capability of the sense amplifier drive circuit shown in FIG. 13; and

FIG. 19 is an operation waveform diagram of the circuit shown in FIG. 18.

### DETAILED DESCRIPTION OF THE EMBODIMENTS

Preferred embodiments of the present invention will be explained below in detail with reference to the accompanying drawings.

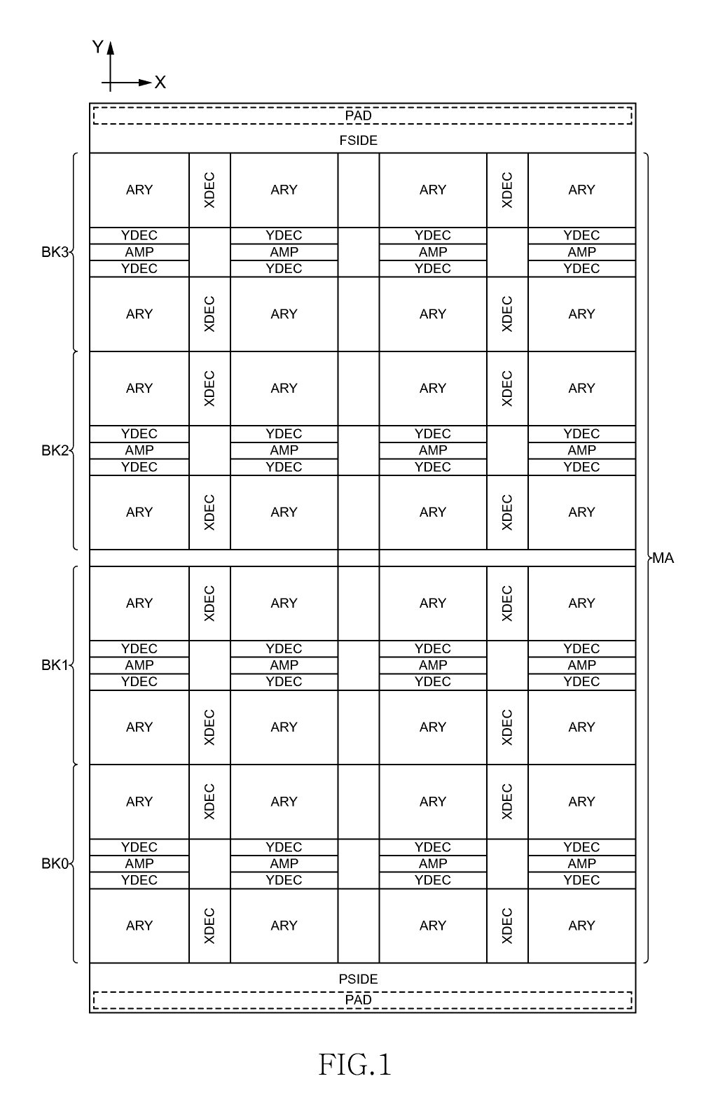

Referring now to FIG. 1, while the present embodiment is an example in which the present invention is applied to a DRAM, the application of the present invention is not limited to DRAMs.

The semiconductor device shown in FIG. 1 is constituted by a semiconductor chip including a memory area MA in which eight memory banks BK0 to BK7 are formed and a peripheral circuit area positioned on both sides of the memory area MA in a Y direction.

The peripheral circuit area includes a first peripheral circuit area PSIDE including a pad area PAD that is arranged along an edge of the semiconductor chip, and a second peripheral circuit area FSIDE including another pad area PAD that is arranged along another edge of the semiconductor chip, which arranged on the opposite side to the first peripheral circuit area PSIDE. In many DRAMs, a pad area is provided in the center of a semiconductor chip; however, when a large number of data I/O pins (32 pins, for example) are provided, it becomes difficult to provide the pad area in the center of the semiconductor chip. In this case, as shown in FIG. 1, a plurality of pad areas is provided in the edges of the semiconductor chip. However, it is not necessary that a semiconductor device according to the present invention has such layout. Therefore, a pad area can be provided in the center of a semiconductor chip.

In the first peripheral circuit area PSIDE, an input receiver that receives an address input via an address pin and an address latch circuit that latches the address are formed. In the second peripheral circuit area FSIDE, an output buffer that outputs read data to a data I/O pin provided in the pad area PAD, and an input receiver that receives write data supplied via the data I/O pin are formed.

The memory area MA is arranged between the first peripheral circuit area PSIDE and the second peripheral circuit area FSIDE. Among the memory banks BK0 to BK7 formed in the memory area MA, the memory banks BK0 to BK3 which are half of the memory banks are arranged in this order along a Y direction in a left half of the semiconductor chip in an X direction. The memory banks BK4 to BK7 which are remaining half of the memory banks are arranged in this order along the Y direction in a right half of the semiconductor chip in the X direction

Each of the memory banks BK0 to BK7 provided in the memory area MA includes two memory cell array areas ARY, a row decoder XDEC or a repeater circuit XREP provided adjacently to one side of each of the memory cell array areas ARY in the X direction, column decoders YDEC and main amplifiers AMP provided adjacently to both sides of each of the memory cell array areas ARY in the Y direction. Although it is not particularly limited, two memory cell array areas ARY belong to the same memory bank are selected by an address bit Y1 included in a column address.

The row decoder XDEC is a circuit that selects a plurality of sub-word lines contained in the memory cell array areas ARY on the basis of a row address. The repeater circuit XREP is a circuit that relays an output signal of the row decoder XDEC. The column decoder YDEC is a circuit that selects a plurality of sense amplifiers contained in the memory cell array area ARY on the basis of the column address. The selected sense amplifiers are connected to the main amplifiers AMP via amain input/output line (MIO), which will be described later.

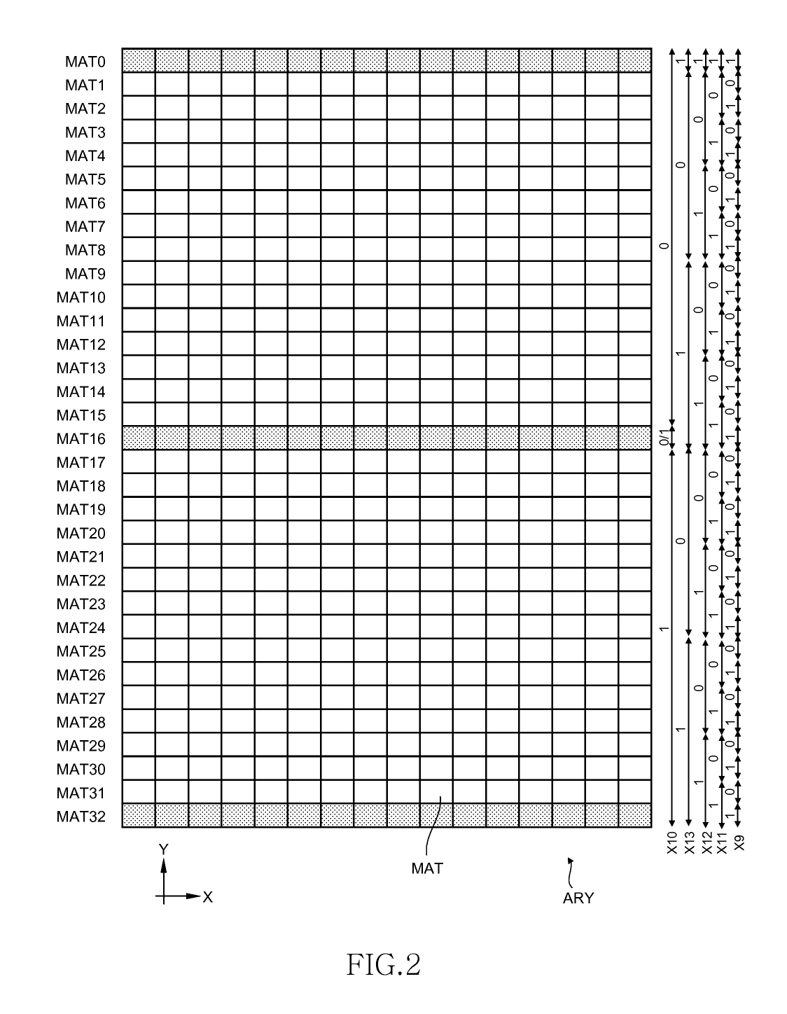

Turning to FIG. 2, the memory cell array area ARY includes a plurality of memory mats MAT that are arranged in matrix. The memory mat MAT is an area in which sub-word lines and bit lines (both described later) extend. Memory mats MAT arranged in a Y direction are selected by mat addresses X9 to X13 that are part of the row address. Memory mats MAT arranged in an X direction are selected by address bits Y0 and Y11 that are part of the column address.

The following describes how addresses of memory mats MAT0 to MAT32, which are arranged in the Y-direction, are assigned. As shown in FIG. 2, one or two of the memory mats MAT0 to MAT32 are selected based on mat addresses X9 to X13. Two memory mats are selected only when all the logic levels of address bits X9 and X11 to X13, which are contained in the mat address, are 1 (high level). In this case, if the address bit X10, which is contained in the mat address, is 0 (low level), both the memory mats MAT0 and MAT16 are selected. If the address bit X10 is 1 (high level), both memory mats MAT16 and MAT32 are selected.

The memory mats MAT0 and MAT32, which positioned in the Y-direction end portions, are so-called end mats. The memory mats MAT0 and MAT32 only have half the number of bit lines of the other memory mats MAT1 to MAT31. Therefore, even though 33 memory mats are arranged in the Y-direction, the capacity value is worth that of 32 mats. Furthermore, the central memory mat MAT16 is a shared memory mat, which is made by combining two end mats. That is, an end mat that should be selected at the same time as the memory mat MAT0, and an end mat that should be selected at the same time as the memory mat MAT32 are combined to form one memory mat. In FIG. 2, the memory mats MAT0 and MAT32, which are end mats, and the shared memory mat MAT16 are shaded.

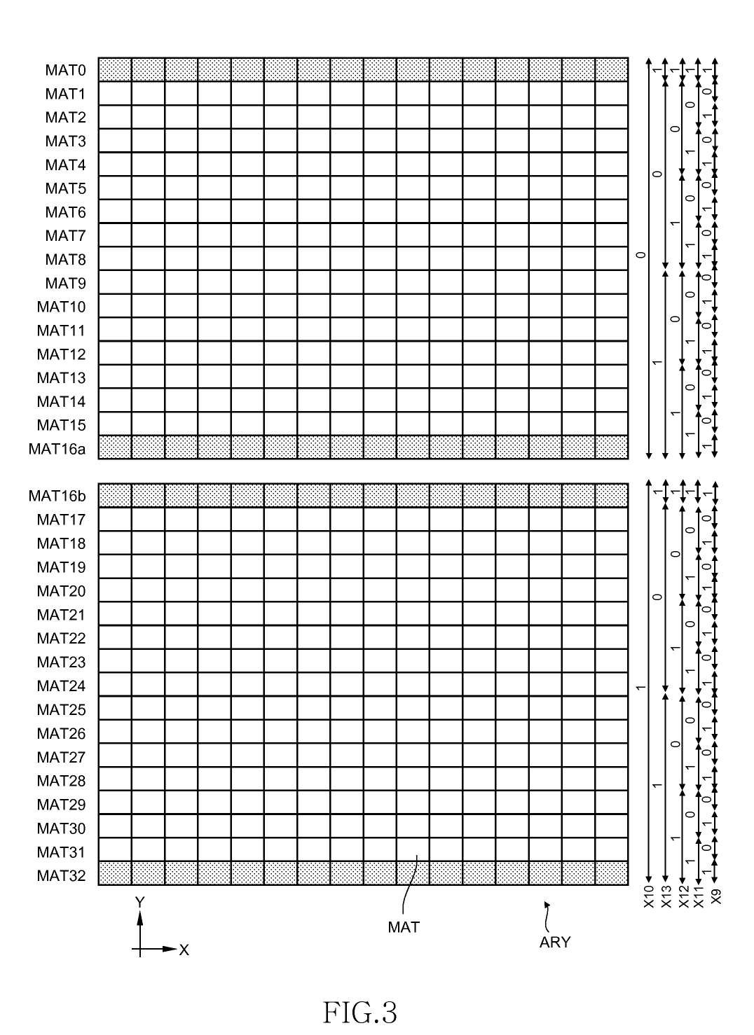

Turning to FIG. 3, if a virtual end mat that should be selected at the same time as the memory mat MAT0 is represented by MAT16a, and a virtual end mat that should be selected at the same time as the memory mat MAT32 is represented by MAT16b, the two end mats MAT16a and MAT16b are combined together to form one shared memory mat MAT16 as shown in FIG. 2. Therefore, as shown in FIG. 3, the memory mats cannot be individually selected, such as when the memory mat MAT16a and the memory mat MAT16b are separated. The memory mats are always selected at the same time.

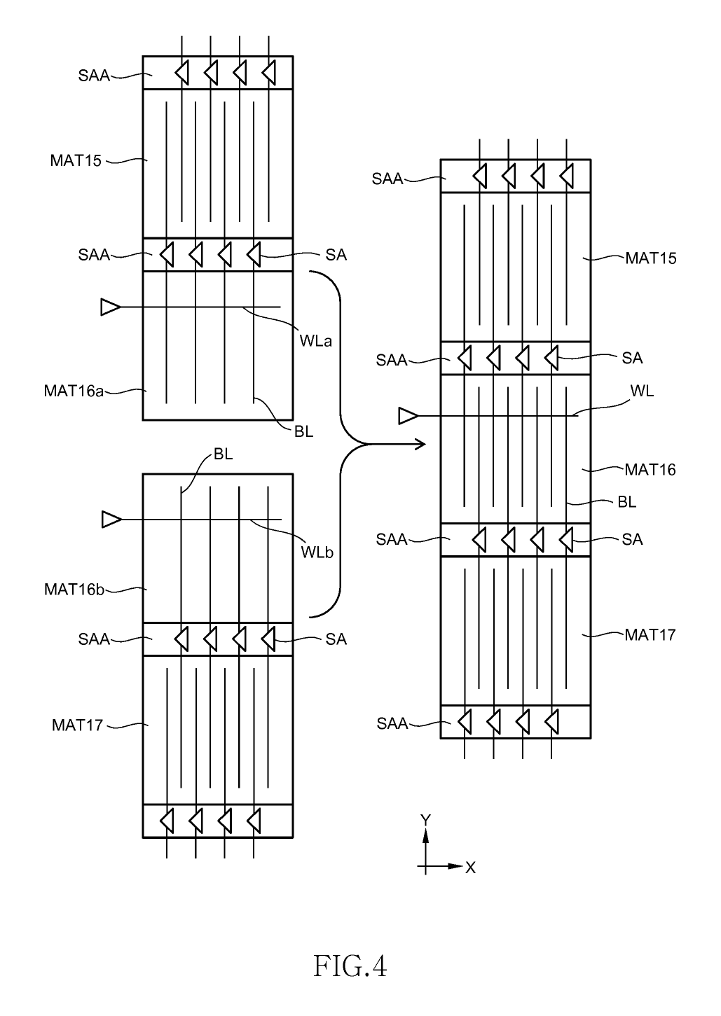

Turning to FIG. 4, as for both the end mats MAT16a and MAT16b, a sense amplifier area SAA is provided only on one Y-direction side. Therefore, the number of bit lines BL provided is one-half of the number of bit lines of a normal memory mat (e.g. MAT15) in which sense amplifier areas SAA are provided on both sides. If the above-described end mats MAT16a and MAT16b are combined, as shown in FIG. 4, the two end mats MAT16a and MAT16b can have the same structure as one normal memory mat. However, unlike the situation where the end mats have not yet be combined, a sub-word line WLa, which is assigned to the end mat MAT16a, and a sub-word line WLb, which is assigned to the end mat MAT16b, cannot be separately provided. Therefore, each sub-word line WL that is assigned to the memory mat MAT16 crosses all the bit lines BL. Incidentally, the memory mats MAT0 and MAT32, which are end mats, have the same structure as the end mats MAT16a and MAT16b shown in FIG. 4.

In that manner, the memory mat MAT16 has the same structure as other normal memory mats. However, half of the bit lines BL are bit lines that should be selected at the same time as the bit lines BL contained in the memory mat MAT0. The remaining half of the bit lines BL are bit lines that should be selected at the same time as the bit lines BL contained in the memory mat MAT32. In that respect, the memory mat MAT16 is different from other normal memory mats.

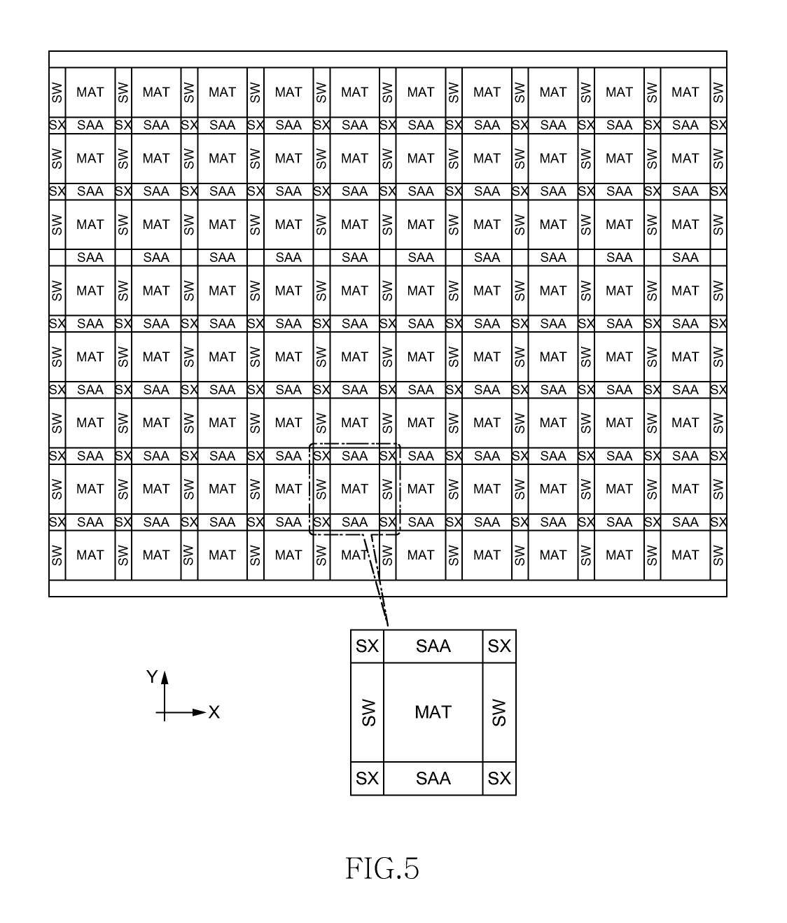

Turning to FIG. 5, between two memory mats MAT that are adjacent to each other in the X-direction, a sub-word driver area SW is provided. Between two memory mats MAT that are adjacent to each other in the Y-direction, a sense amplifier area SAA is provided. In an area where a string of sub-word driver areas SW extending in the Y-direction crosses a string of sense amplifier areas SAA extending in the X-direction, a sub-word cross area SX is provided. In the sub-word cross area SX, a sub amplifier, which is used to drive a main input/output line (described later), and the like are disposed.

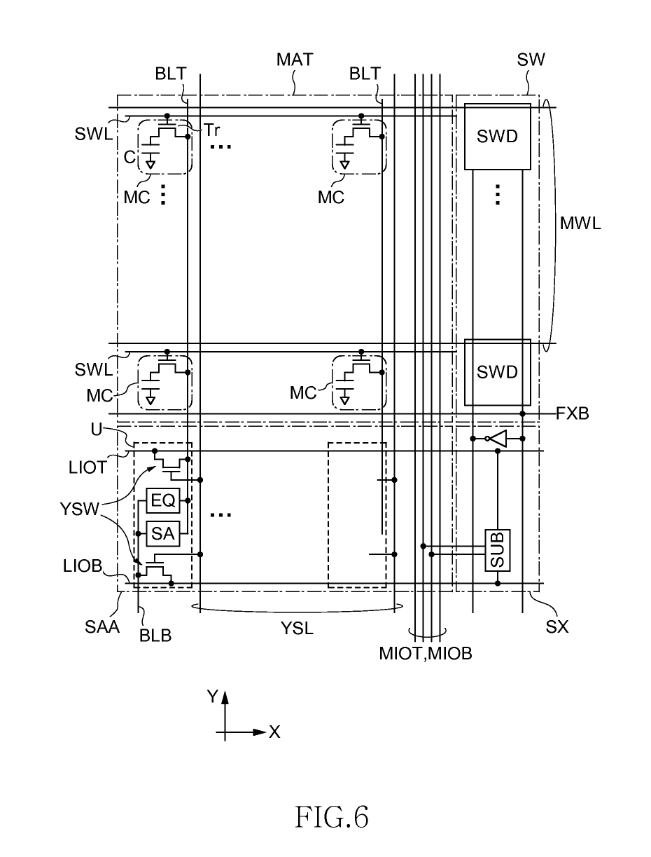

Turning to FIG. 6, local input/output lines LIOT and LIOB extending in the X direction and main input/output lines MIOT and MIOB extending in the Y direction are provided in the memory cell array area ARY. The local input/output lines LIOT and LIOB and the main input/output lines MIOT and MIOB are hierarchically structured input/output lines.

The local input/output lines LIOT and LIOB are used for transferring read data read out from a memory cell MC and write data to be written to the memory cell MC in the memory cell array area ARY. The local input/output lines LIOT and LIOB are differential data input/output lines for transferring read data and write data by using a pair of lines. The local input/output lines LIOT and LIOB are laid out in the X direction on the sense amplifier area SAA and the sub-word cross area SX.

The main input/output lines MIOT and MIOB are used for transferring read data from the memory cell array area ARY to the main amplifier AMP and transferring write data from the main amplifier AMP to the memory cell array area ARY. The main input/output lines MIOT and MIOB are also differential data input/output lines for transferring read data and write data by using a pair of lines. The main input/output lines MIOT and MIOB are laid out in the Y direction on the memory cell array area ARY and the sense amplifier area SAA. A number of main input/output lines MIOT and MIOB extending in the Y direction are provided in parallel to each other and are connected to the main amplifier AMP provided in the main amplifier area.

In the memory mat MAT, memory cells MC are arranged at respective intersections of sub-word lines SWL extending in the X direction and bit lines BLT or BLB extending in the Y direction. The memory cell MC has a configuration in which a cell transistor Tr and a cell capacitor C are connected in series between a corresponding one of the bit lines BLT or BLB and a plate wiring (such as a pre-charge line). The cell transistor Tr is constituted by an n-channel MOS transistor, and a gate electrode thereof is connected to a corresponding one of the sub-word lines SWL.

A number of sub-word drivers SWD are provided in the sub-word driver area SW. Each of the sub-word drivers SWD drives a corresponding one of the sub-word lines SWL according to the row address.

Furthermore, a plurality of main word lines MWL and a plurality of word-driver selection lines FXB are connected to the sub-word drivers SWD. For example, eight word-driver selection lines FXB are wired on one sub word driver SWD, one sub-word line SWL is activated by selecting any one of four sub-word drivers SWD by a pair of word-driver selection lines FXB.

In the sense amplifier area SAA, a number of sense amplifiers SA, equalizer circuits EQ, and column switches YSW are arranged. Each of the sense amplifiers SA and the equalizer circuits EQ is connected to a corresponding one of pairs of the bit lines BLT and BLB. The semiconductor device according to the present embodiment has so-called open bitline structure. Therefore, bit lines BLT and BLB included in a bit line pair connected to one sense amplifier SA are arranged in different memory mats MAT (that is, two memory mats MAT that are adjacent to each other in the Y direction), respectively. The sense amplifier SA amplifies a potential difference generated in the corresponding one of pairs of the bit lines BLT and BLB, while the equalizer circuits EQ equalize potentials in the corresponding one of pairs of the bit lines BLT and BLB to the same level. Read data amplified by the sense amplifier SA is transferred to the local input/output lines LIOT and LIOB, and then further transferred to the main input/output lines MIOT and MIOB from these local input/output lines.

The column switches YSW are respectively provided between the corresponding sense amplifier SA and the local input/output lines LIOT and LIOB, and connect the sense amplifier SA and the local input/output lines LIOT and LIOB by causing corresponding column selection lines YSL to be activated at a high level. An end of the column selection line YSL is connected to the column decoder YDEC, and the column decoder YDEC activates any of the column selection lines YSL based on the column address.

A plurality of sub-amplifiers SUB are provided in the sub-word cross area SX. The sub-amplifiers SUB are provided in plural numbers for each sub-word cross area SX and drives corresponding main input/output lines MIOT and MIOB. An input terminal of each of the sub-amplifiers SUB is connected to a corresponding pair of the local input/output lines LIOT and LIOB, and an output terminal of each of the sub-amplifiers SUB is connected to corresponding ones of the main input/output lines MIOT and MIOB. Each of the sub-amplifiers SUB respectively drives the main input/output lines MIOT and MIOB according to data on corresponding ones of the local input/output lines LIOT and LIOB. Instead of the sub-amplifier SUB, so-called path gate that connects the main input/output lines MIOT and MIOB and the local input/output lines LIOT and LIOB by n-channel MOS transistor may be used.

As described above, the main input/output lines MIOT and MIOB are provided to pass over the memory mat MAT. Furthermore, an end of each of the main input/output lines MIOT and MIOB is connected to the main amplifier AMP provided in the main amplifier area. With this configuration, data read out by using the sense amplifier SA is transferred to the sub-amplifier SUB via the local input/output lines LIOT and LIOB, and the data is then transferred to the main amplifier AMP via the main input/output lines MIOT and MIOB. The main amplifier AMP further amplifies data supplied via the main input/output lines MIOT and MIOB.

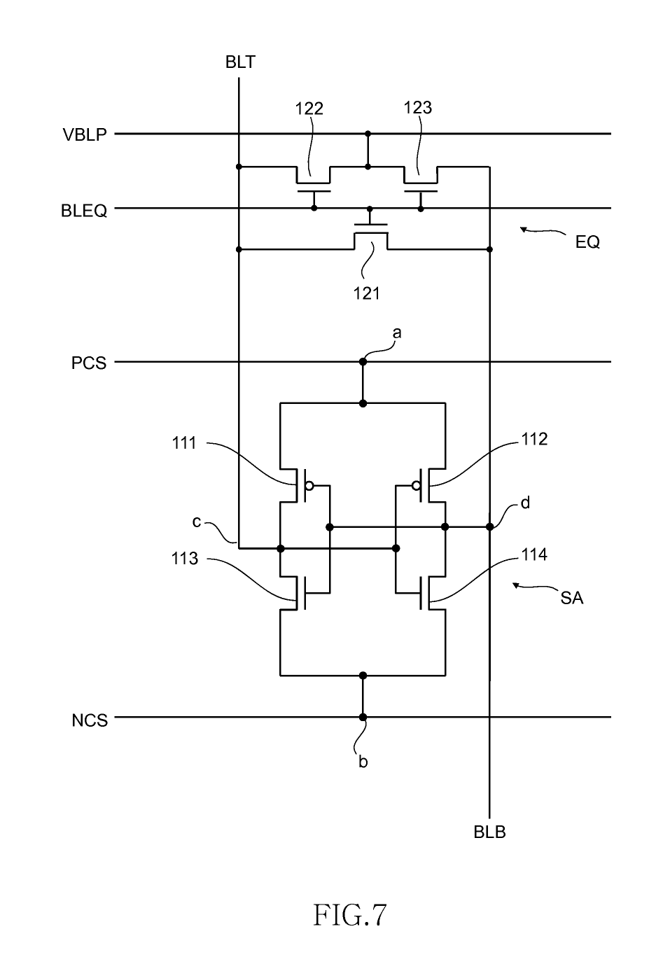

Turning to FIG. 7, the sense amplifier SA includes p-channel MOS transistors 111 and 112 and n-channel MOS transistors 113 and 114. The transistors 111 and 113 are connected in series between common source nodes a and b. A contact point of the transistors 111 and 113 is connected to one signal node c. The gate electrodes of the transistors 111 and 113 are connected to the other signal node d. Similarly, the transistors 112 and 114 are connected in series between the common source nodes a and b. A contact point of the transistors 112 and 114 is connected to one signal node d. The gate electrodes of the transistors 112 and 114 are connected to the other signal node c. The signal node c is connected to a bit line BLT, and the signal node d is connected to a bit line BLB.

Because of the above flip-flop structure, in the situation where predetermined active potentials are being supplied to a high-side common source line PCS and a low-side common source line NCS, if a potential difference occurs between the bit lines BLT and BLB that are paired, the potential of the high-side common source line PCS is supplied to one of the bit lines paired, and the potential of the low-side common source line NCS to the other one of the bit lines paired. The active potential of the high-side common source line PCS is an array potential VARY. The active potential of the low-side common source line NCS is a ground potential VSS.

Before a sense operation is performed, the pair of bit lines BLT and BLB is equalized by the equalizing circuit EQ in advance so as to be a pre-charge potential VBLP. After the equalizing is stopped, a sub-word line WL corresponding to a memory cell MC connected to one of the bit lines BLT and BLB is selected, and only the one of the bit lines BLT and BLB is discharged. As a result, a potential difference occurs between the two bit lines BLT and BLB. After that, as the active potentials are supplied to the common source lines PCS and NCS, the potential difference of the bit lines BLT and BLB paired becomes amplified.

The equalizing circuit EQ includes three n-channel MOS transistors 121 to 123. The transistor 121 is connected between the bit lines BLT and BLB paired. The transistor 122 is connected between the bit line BLT and a line to which the pre-charge potential VBLP is supplied. The transistor 123 is connected between the bit line BLB and the line to which the pre-charge potential VBLP is supplied. To the gate electrodes of all the transistors 121 to 123, a bit line equalizing signal BLEQ is supplied. According to the above configuration, when the bit line equalizing signal BLEQ is activated to a high level, the pair of bit lines BLT and BLB is pre-charged so as to be the pre-charge potential VBLP.

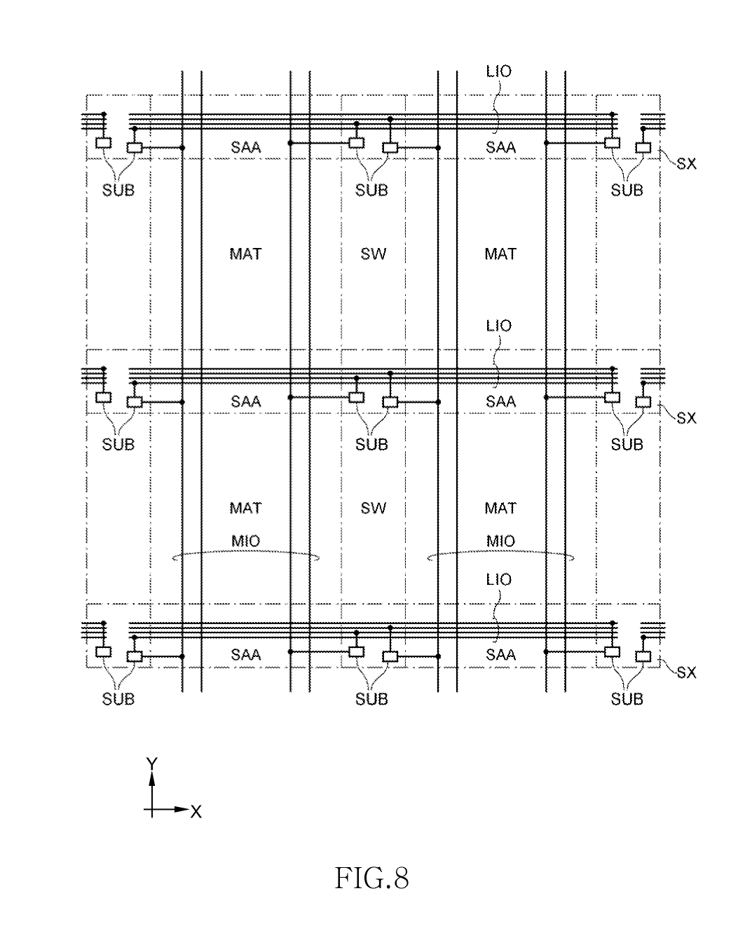

Turning to FIG. 8, in this example, in a sense amplifier area SAA, four pairs of local input/output lines LIOT and LIOB are provided. Therefore, in total, eight local input/output lines LIOT and LIOB are provided in the sense amplifier area SAA. In FIG. 8, one pair of local input/output lines LIOT and LIOB is represented by one solid line. In the present example, the X-direction length of each local input/output line is about double the length of a memory mat MAT, meaning that assignment of each local input/output line LIOT or LIOB is in units of two mats. Among the four pairs of local input/output lines LIOT and LIOB, one pair is connected to corresponding main input/output lines MIOT and MIOB via one sub-amplifier SUB that is disposed in a sub-word cross area SX positioned in one end portion. Another pair is connected to corresponding main input/output lines MIOT and MIOB via one sub-amplifier SUB that is disposed in a sub-word cross area SX positioned in the other end portion. The remaining two pairs are connected to corresponding main input/output lines MIOT and MIOB via two sub-amplifiers SUB that are disposed in sub-word cross areas SX positioned at the center, respectively.

Furthermore, according to the present embodiment, the open bitline method is employed. Therefore, when seen from each memory mat MAT, the sense amplifiers SA that are disposed in the sense amplifier areas SAA on both sides in the Y-direction are simultaneously selected. As a result, from one selected memory mat MAT, data is read via eight pairs of local input/output lines LIOT and LIOB (i.e. 16 local input/output lines) and eight pairs of main input/output lines MIOT and MIOB (i.e. 16 main input/output lines) in total. That is, eight pairs of main input/output lines MIOT and MIOB (i.e. 16 main input/output lines) are assigned to each set of two mats.

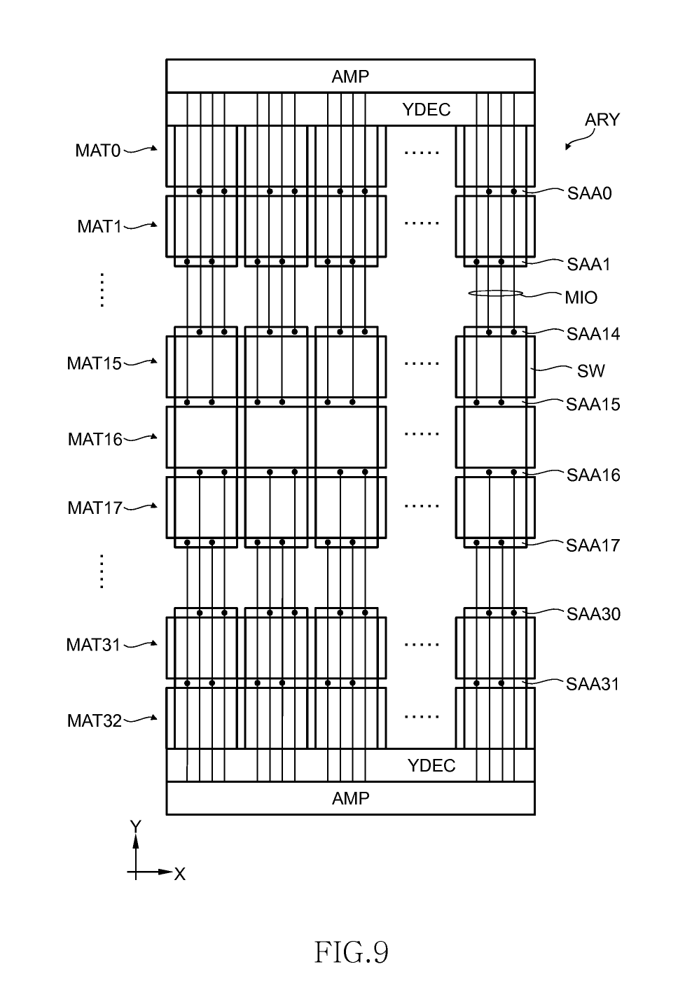

Turning to FIG. 9, according to the present embodiment, to one memory cell array area ARY, two main amplifiers AMP are assigned. One main amplifier AMP is disposed in one Y-direction end portion of the memory cell array area ARY. The other main amplifier AMP is disposed in the other Y-direction end portion of the memory cell array area ARY. That is, the memory cell array area ARY is so formed as to be sandwiched between the two main amplifiers AMP. One main amplifier AMP is connected to sense amplifier areas SAA0 to SAA15, which are disposed between the memory mats MAT0 to MAT16, via a main input/output line MIO. The other main amplifier AMP is connected to sense amplifier areas SAA16 to SAA31, which are disposed between the memory mats MAT16 to MAT32, via a main input/output line MIO. Incidentally, in FIG. 9, one pair of main input/output lines MIO is represented by one solid line.

Each of the main input/output lines MIO is laid out so as to extend in the Y-direction on the memory mats MAT0 to MAT15 or the memory mats MAT17 to MAT32. On the memory mat MAT16, no main input/output line MIO is provided. Each main input/output line MIO is connected to every other sense amplifier area SAA. That is, a main input/output line MIO is connected to even-numbered sense amplifier areas SAA. Another main input/output line MIO is connected to odd-numbered sense amplifier areas SAA.

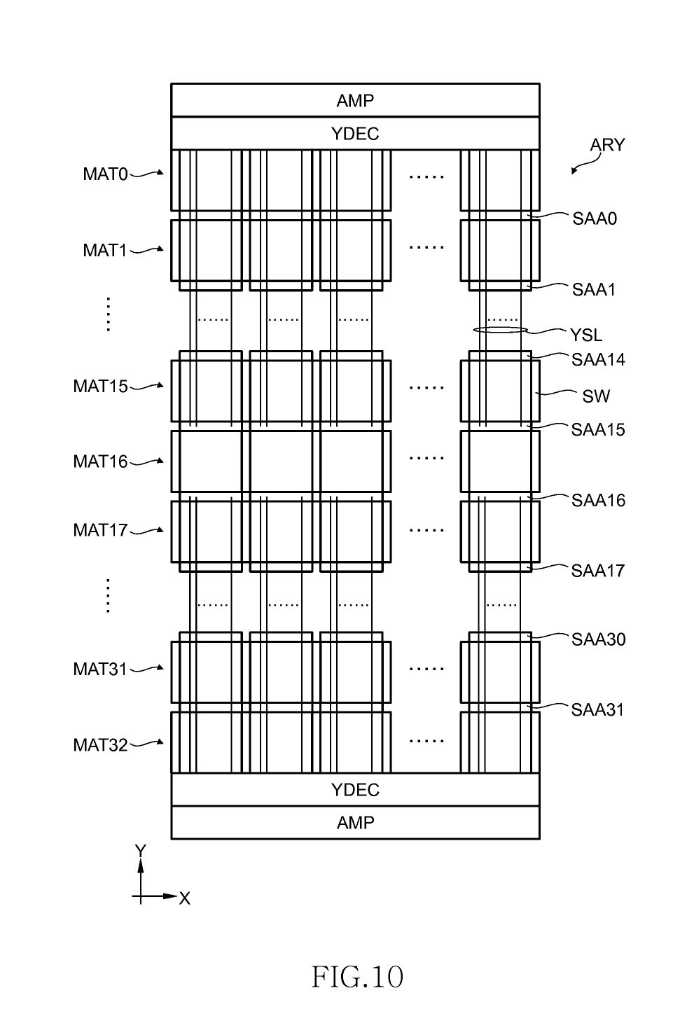

Turning to FIG. 10, according to the present embodiment, to one memory cell array area ARY, two column decoders YDEC are allocated. One column decoder YDEC is disposed in one Y-direction end portion of the memory cell array area ARY. The other column decoder YDEC is disposed in the other Y-direction end portion of the memory cell array area ARY. That is, the memory cell array area ARY is so formed as to be sandwiched between the two column decoders YDEC. One column decoder YDEC is connected to sense amplifier areas SAA0 to SAA15, which are disposed between the memory mats MAT0 to MAT16, via a column selection line YSL. The other column decoder YDEC is connected to sense amplifier areas SAA16 to SAA31, which are disposed between the memory mats MAT16 to MAT32, via a column selection line YSL.

Each of the column selection lines YSL is laid out so as to extend in the Y-direction on the memory mats MAT0 to MAT15 or the memory mats MAT17 to MAT32. On the memory mat MAT16, no column selection line YSL is provided. Unlike the main input/output lines MIO, each column selection line YSL is connected to each sense amplifier area.

The following describes a relationship between a memory mat to be selected, and a sense amplifier area to be activated.

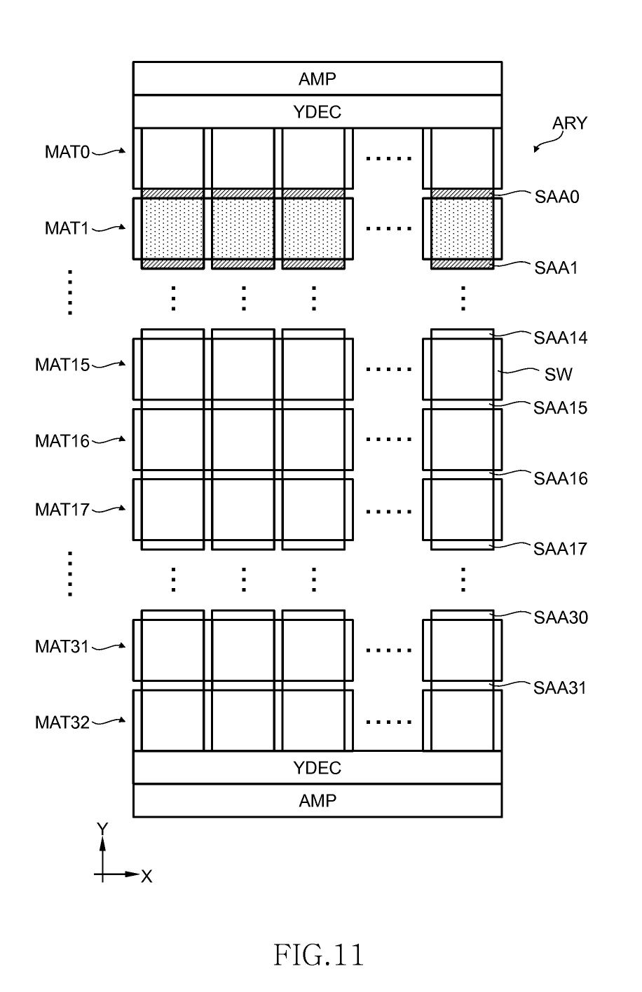

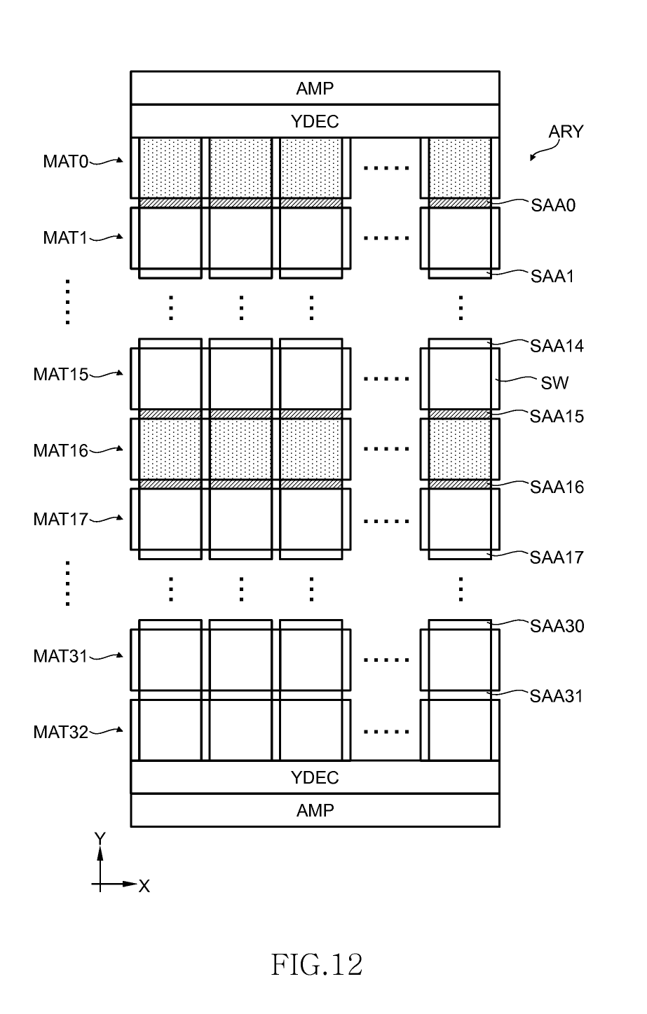

Turning to FIGS. 11 and 12, the selected memory mats are shaded, and the activated sense amplifier areas are hatched.

As shown in FIG. 11, when the memory mat MAT1, which is not an end mat, is selected, the two sense amplifier areas SAA0 and SAA1, which are adjacent to both sides of the memory mat MAT1 in the Y-direction, become activated. A sense amplifier SA contained in the sense amplifier area SAA0 amplifies a potential difference that occurs on a pair of bit lines BLT and BLB disposed in the memory mats MAT0 and MAT1. A sense amplifier SA contained in the sense amplifier area SAA1 amplifies a potential difference that occurs on a pair of bit lines BLT and BLB disposed in the memory mats MAT1 and MAT2. The sense amplifier areas SAA0 and SAA1 each are connected to one-half of the bit lines contained in the memory mat MAT1. Therefore, in all, data is read from all the bit lines contained in the memory mat MAT1. The same operation is performed also when the other memory mats MAT2 to MAT15 and MAT17 to MAT31, which are not end mats, are selected.

On the other hand, as shown in FIG. 12, when the memory mat MAT0, which is an end mat, is selected, the following three sense amplifier areas become activated in total: one sense amplifier area SAA0, which is adjacent to one side of the memory mat MAT0 in the Y-direction, and the two sense amplifier areas SAA15 and SAA16, which are adjacent to both sides of the memory mat MAT16 in the Y-direction. A sense amplifier SA contained in the sense amplifier area SAA0 amplifies a potential difference that occurs on a pair of bit lines BLT and BLB disposed in the memory mats MAT0 and MAT1. A sense amplifier SA contained in the sense amplifier area SAA15 amplifies a potential difference that occurs on a pair of bit lines BLT and BLB disposed in the memory mats MAT15 and MAT16. A sense amplifier SA contained in the sense amplifier area SAA16 amplifies a potential difference that occurs on a pair of bit lines BLT and BLB disposed in the memory mats MAT16 and MAT17.

However, if the memory mat MAT0 is selected, data to be accessed is output signals of sense amplifiers SA contained in the sense amplifier areas SAA0 and SAA15; an output signal of a sense amplifier SA contained in the sense amplifier area SAA16 is not selected. In this case, the sense amplifier areas SAA0 and SAA15 each are connected to one-half of the bit lines contained in one mat. Therefore, in all, data is read from all the bit lines contained in that one mat; the amount of data is equal to that for the case where a memory mat that is not an end mat is selected. The reason why the sense amplifier area SAA16 is activated is to prevent half of data contained in the memory mat MAT 16 from being destroyed; when the sense amplifier area SAA15 is activated, half of the data may be destroyed unless the sense amplifier area SAA16 is activated at the same time.

Incidentally, the same operation is performed also when the memory mat MAT32, which is another end mat, is selected; three sense amplifier areas SAA15, SAA16, and SAA31 are activated in total. However, the data to be accessed is output signals of sense amplifiers SA contained in the sense amplifier areas SAA16 and SAA31; an output signal of a sense amplifier SA contained in the sense amplifier area SAA15 is not selected.

In the case of the operation described above, even when an end mat is selected, or when a memory mat that is not an end mat is selected, it is possible to access one-mat's worth of bit lines. According to the present embodiment, there are two end mats where only half of bit lines are provided. Therefore, unlike the case (see FIG. 3) where the memory bank is divided into two in the Y-direction, there is no increase in the area of the chip. Moreover, as in the case where the memory bank is divided into two in the Y-direction, the length of the main input/output lines MIO and column selection lines YSL is limited to about one-half of the Y-direction length of the memory bank. Therefore, it is possible to increase the access speed. Thus, according to the present embodiment, it is possible to increase the access speed while preventing an increase in the area of the chip.

However, according to the present embodiment, the number of sense amplifier areas activated is different between when an end mat is selected and when a memory mat that is not an end mat is selected. Therefore, there is a possibility of causing a difference in sense characteristics. The following describes the problem and measures that are taken to address the problem.

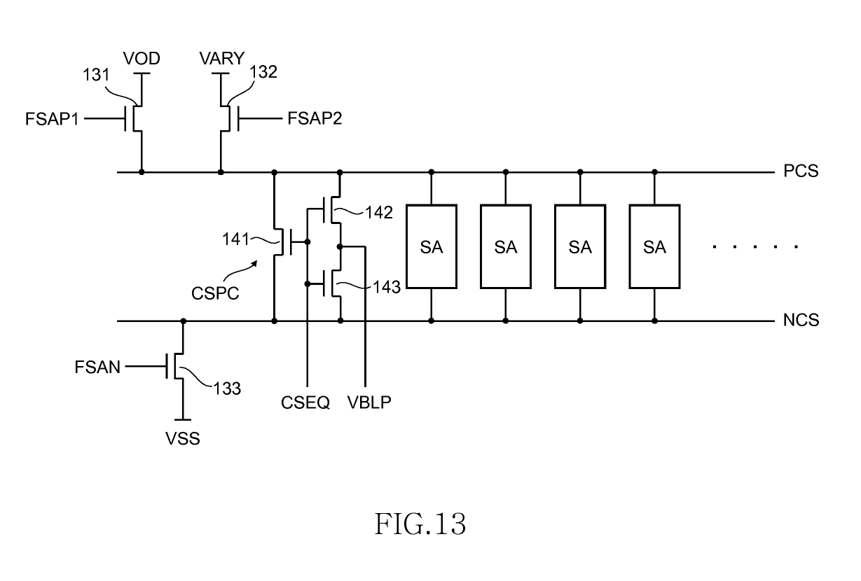

Turning to FIG. 13, to the high-side common source line PCS, n-channel MOS transistors 131 and 132 are connected. To the source of the transistor 131, an overdrive potential VOD is supplied; to the gate electrode of the transistor 131, a timing signal FSAP1 is supplied. To the source of the transistor 132, the array potential VARY is supplied; to the gate electrode of the transistor 132, a timing signal FSAP2 is supplied. As the timing signal FSAP1 is activated to a high level, the common source line PCS is driven to the overdrive potential VOD. As the timing signal FSAP2 is activated to a high level, the common source line PCS is driven to the array potential VARY.

To the low-side common source line NCS, a n-channel MOS transistor 133 is connected. To the source of the transistor 133, the ground potential VSS is supplied; to the gate electrode of the transistor 133, a timing signal FSAN is supplied. As the timing signal FSAN is activated to a high level, the common source line NCS is driven to the ground potential VSS.

Between the common source lines PCS and NCS, a common source pre-charge circuit CSPC is connected. The common source pre-charge circuit CSPC has a similar circuit configuration to that of the equalizing circuit EQ shown in FIG. 7. The common source pre-charge circuit CSPC has three n-channel MOS transistors 141 to 143. The transistor 141 is connected between the common source lines PCS and NCS. The transistor 142 is connected between the common source line PCS, and a line to which the pre-charge potential VBLP is supplied. The transistor 143 is connected between the common source line NCS, and the line to which the pre-charge potential VBLP is supplied. To the gate electrodes of all the transistors 141 to 143, a common source equalizing signal CSEQ is supplied. According to the above configuration, as the common source equalizing signal CSEQ is activated to a high level, the common source lines PCS and NCS are pre-charged so as to be at the pre-charge potential VBLP.

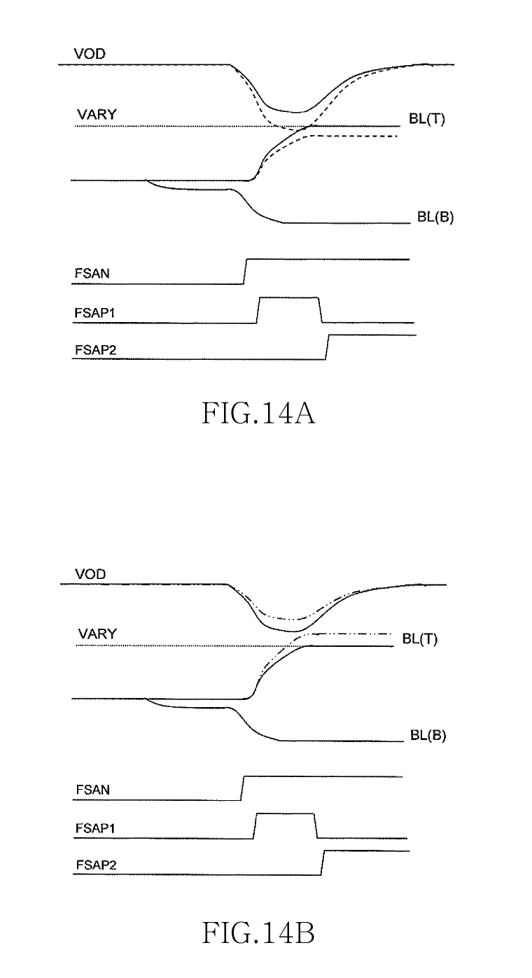

In the case of the above circuit configuration, if the overdrive capability is so designed as to be suitable for the case where a memory mat that is not an end mat is selected, the overdrive capability may become insufficient when an end mat is selected. If the overdrive capability is so designed as to be suitable for the case where an end mat is selected, the overdrive capability may become excessive when a memory mat that is not an end mat is selected. FIG. 14 is waveform diagrams illustrating the above situation; FIG. 14A shows the case where the overdrive capability is insufficient, and FIG. 14B shows the case where the overdrive capability is excessive.

As shown in FIG. 14A, if the overdrive capability is so designed as to be suitable for the case where a memory mat that is not an end mat is selected, desired overdrive characteristics can be obtained, as indicated by solid line, at a time when a memory mat that is not an end mat is selected. However, if an end mat is selected, a drop in overdrive potential VOD becomes large due to the insufficient overdrive capability; the potential of the bit line BLT that should be driven to a high level reaches VARY later than designed. Incidentally, the timing signal FSAP1 is a signal that is driven to a high level in response to the rising of the timing signal FSAN and remains at the high level for a predetermined period. The timing signal FSAP2 is a signal that is driven to a high level in response to the falling of the timing signal FSAP1.

As shown in FIG. 14B, if the overdrive capability is so designed as to be suitable for the case where an end mat is selected, desired overdrive characteristics can be obtained, as indicated by solid line, at a time when an end mat is selected. However, if a memory mat that is not an end mat is selected, the overdrive capability becomes excessive. As a result, the potential of the bit line BLT that should be driven to a high level temporarily exceeds VARY. Even if the potential of the bit line BLT temporarily exceeds VARY, the potential of the bit line BLT returns to VARY as the timing signal FSAP2 is activated. Therefore, there is no great adverse impact on the actual operation. However, a power supply circuit needs to be larger in size to obtain the overdrive capability, resulting in an increase in current consumption.

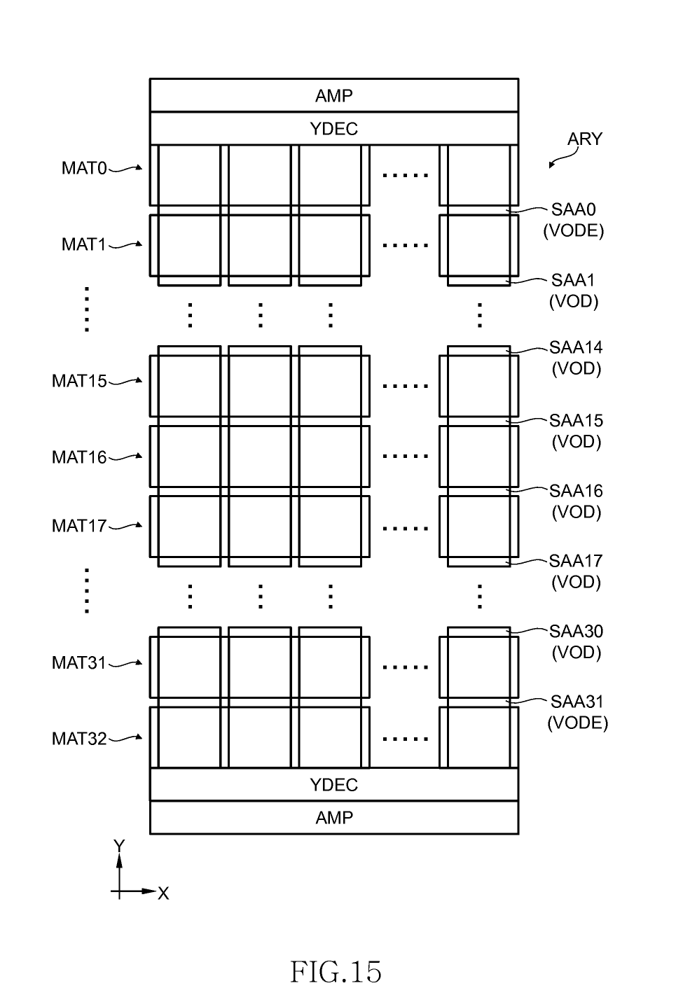

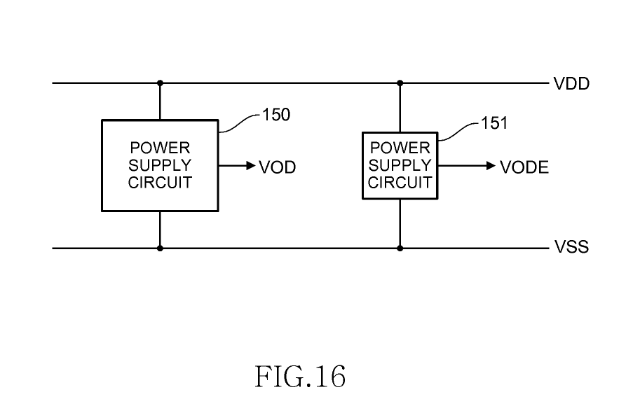

Such a problem can be solved by supplying another overdrive potential VODE to the sense amplifier areas SAA0 and SAA31 that are adjacent to the end mats as shown in FIG. 15. The level of the overdrive potential VODE is equal to the level of the overdrive potential VOD. However, as shown in FIG. 16, the overdrive potentials VOD and VODE are generated by different power supply circuits 150 and 151, respectively. The power supply capability of the power supply circuit 151 that generates the overdrive potential VODE is so designed as to be one-half of the power supply capability of the power supply circuit 150 that generates the overdrive potential VOD. Both power-source potentials VDD and VSS that are supplied to the power supply circuits 150 and 151 are external power-source potentials that are supplied from the outside.

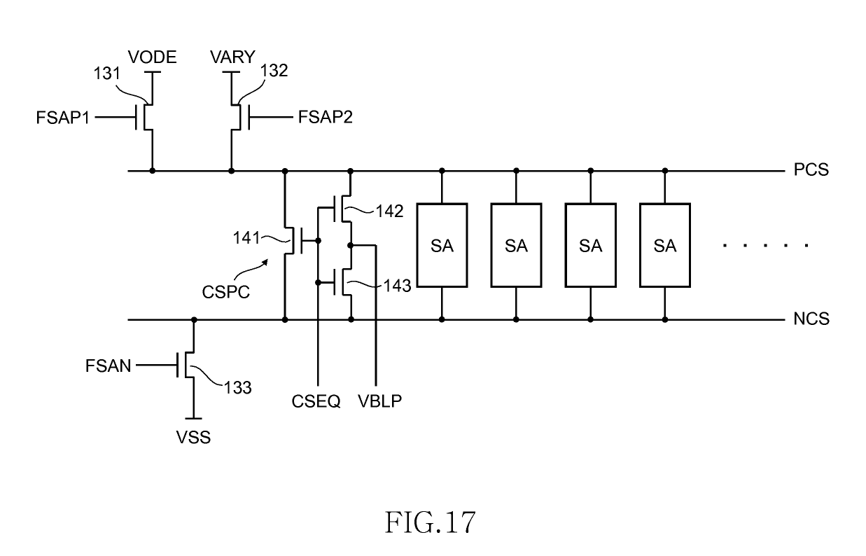

Turning to FIG. 17, for the sense amplifier areas SAA0 and SAA31, instead of the overdrive potential VOD, the overdrive potential VODE is used. For the other sense amplifier areas SAA1 to SAA30, the sense amplifier drive circuit shown in FIG. 13 is used to drive the common source lines PCS and NCS.

Accordingly, when a memory mat that is not an end mat is selected, the overdrive potential VOD is basically supplied only from the power supply circuit 150. When an end mat is selected, the overdrive potential VOD is supplied from the power supply circuit 150, and the overdrive potential VODE is supplied from the power supply circuit 151. Since the power supply capability of the power supply circuit 151 is half of that of the power supply circuit 150, the overdrive capability at a time when an end mat is selected is 1.5 times larger than when a memory mat that is not an end mat is selected. The number of sense amplifier areas activated at a time when an end mat is selected is 1.5 times larger than when a memory mat that is not an end mat is selected. Therefore, according to the present embodiment, whichever memory mat is selected, the same overdrive characteristics can be obtained.

Incidentally, in the present example, even when a memory mat (MAT1 or MAT31) that is adjacent to an end mat is selected, the overdrive capability becomes 1.5 times larger. However, as described above, the excessive overdrive capability does not have an adverse impact on the actual operation.

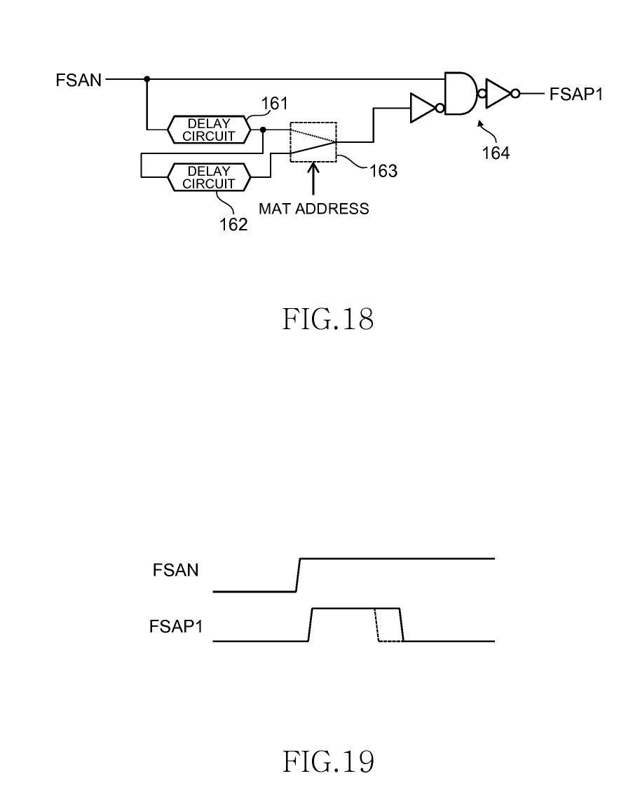

The circuit shown in FIG. 18 is a circuit that generates a timing signal FSAP1. The circuit includes a switch circuit 163 that can switch in response to a selected memory mat. The switch circuit 163 selects an output signal of a delay circuit 161 at a time when a memory mat that is not an end mat is selected. The switch circuit 163 selects an output signal of a delay circuit 162 at a time when an end mat is selected. As shown in FIG. 18, the delay circuits 161 and 162 are connected in series, and a timing signal FSAN is input to the delay circuit 161. The timing signal FSAN and an output signal of the switch circuit 163 are supplied to a gate circuit 164. An output signal of the gate circuit 164 is used as a timing signal FSAP1.

According to the above configuration, as shown in FIG. 19, the pulse width of the timing signal FSAP1 becomes relatively short (dashed line) at a time when a memory mat that is not an end mat is selected. When an end mat is selected, the pulse width of the timing signal FSAP1 becomes relatively long (solid line). In this manner, the overdrive capability is optimized in response to a selected memory mat. As a result, it is possible to obtain desired overdrive characteristics.

It is apparent that the present invention is not limited to the above embodiments, but may be modified and changed without departing from the scope and spirit of the invention.

What is claimed is:

1. A semiconductor device comprising:
a plurality of memory mats arranged in a first direction and selected based on a mat address, the plurality of memory mats including a first memory mat disposed in one end portion of the first direction, a second memory mat disposed in the other end portion of the first direction, and a third memory mat positioned between the first and second memory mats; and
a plurality of sense amplifier areas each arranged between two of the memory mats that are adjacent to each other in the first direction, each of the sense amplifier areas including a plurality of sense amplifiers, wherein
each of the memory mats includes a plurality of bit lines extending in the first direction, a plurality of word lines extending in a second direction that crosses the first direction, and a plurality of memory cells disposed at intersections of the bit lines and word lines,
each of the sense amplifiers is connected to an associated one of the bit lines included in an adjacent one of the memory mats on one side of the first direction, and to an associated one of the bit lines included in an adjacent one of the memory mats on the other side of the first direction,
the first and third memory mats are selected when the mat address indicates a first value, and
the second and third memory mats are selected when the mat address indicates a second value that is different from the first value.

2. The semiconductor device as claimed in claim 1, wherein
the plurality of sense amplifier areas include a first sense amplifier area provided adjacent to the first memory mat, a second sense amplifier area provided adjacent to the second memory mat, and a third and a fourth sense amplifier areas provided adjacent to the third memory mat such that the third memory mat is sandwiched therebetween,
the sense amplifiers included in the first, third, and fourth sense amplifier areas are activated when the mat address indicates the first value, and
the sense amplifiers included in the second, third and fourth sense amplifier areas are activated when the mat address indicates the second value.

3. The semiconductor device as claimed in claim 2, wherein
the plurality of memory mats further include a fourth memory mat provided adjacent to the third memory mat,
the fourth memory mat is selected when the mat address indicates a third value that is different from the first and second values,
the plurality of sense amplifier areas further include a fifth sense amplifier area,
the fourth memory mat is disposed between the third and fifth sense amplifier areas, and
the sense amplifiers included in the third and fifth sense amplifier areas are activated when the mat address indicates the third value.

4. The semiconductor device as claimed in claim 3, further comprising a sense amplifier drive circuit supplying an operation potential to activated ones of the sense amplifiers,
wherein the sense amplifier drive circuit supplies the operation potential in a first capability when the mat address indicates the first or second value, and supplies the operation potential in a second capability that is lower than the first capability when the mat address indicates the third value.

5. The semiconductor device as claimed in claim 4, further comprising:
first and second drive lines connected to the sense amplifiers; and
first and second power supply circuit generating an overdrive potential, wherein
the sense amplifiers are operated on a potential difference between the first and second drive lines,
the sense amplifier drive circuit includes a first drive circuit supplying a first operation potential to the first drive line, a second drive circuit supplying a second operation potential that is higher than the first operation potential to the second drive line, and an overdrive circuit supplying the overdrive potential that is higher than the second operation potential to the second drive line,
the overdrive potential is supplied to the overdrive circuit via both the first and second power supply circuits when the mat address indicates the first or second value, and
the overdrive potential is supplied to the overdrive circuit via one of the first and second power supply circuits when the mat address indicates the third value.

6. The semiconductor device as claimed in claim 4, further comprising:
first and second drive lines connected to the sense amplifiers; and
first and second power supply circuit generating an overdrive potential, wherein
the sense amplifiers are operated on a potential difference between the first and second drive lines,
the sense amplifier drive circuit includes a first drive circuit supplying a first operation potential to the first drive line, a second drive circuit supplying a second operation potential that is higher than the first operation potential to the second drive line, and an overdrive circuit supplying the overdrive potential that is higher than the second operation potential to the second drive line,
the sense amplifier drive circuit, when the mat address indicates the first or second value, activates the second drive circuit after activating the overdrive circuit during a first period of time, and
the sense amplifier drive circuit, when the mat address indicates the third value, activates the second drive circuit after activating the overdrive circuit during a second period of time that is shorter than the first period.

7. The semiconductor device as claimed in claim 1, further comprising:
a plurality of data input/output lines;
a plurality of column switches each connected between an associated one of the data input/output lines and an associated one of the sense amplifiers, the column switches including first column switches disposed between the first memory mat and the third memory mat and second column switches disposed between the second memory mat and the third memory mat;
a first column decoder controlling the first column switches; and
a second column decoder controlling the second column switches.

8. The semiconductor device as claimed in claim 7, wherein the plurality of memory mats are disposed between the first and second column decoders.

9. The semiconductor device as claimed in claim 8, further comprising first and second main amplifiers, wherein
the plurality of data input/output lines include a plurality of local input/output lines extending in the second direction and connected to the plurality of sense amplifiers via the plurality of column switches, and a plurality of main input/output lines extending in the first direction and connecting one of the first and second main amplifiers to the plurality of local input/output lines,
the main input/output lines including first main input/output lines connected to the local input/output lines disposed between the first memory mat and the third memory mat, and second main input/output lines connected to the local input/output lines disposed between the second memory mat and the third memory mat,
the first main amplifier is connected to the first main input/output lines, and
the second main amplifier is connected to the second main input/output lines.

10. The semiconductor device as claimed in claim 9, wherein the plurality of memory mats are disposed between the first and second main amplifiers.

11. A semiconductor device comprising:
a plurality of memory mats arranged in a first direction, the plurality of memory mats including a first memory mat disposed in one end portion of the first direction, a second memory mat disposed in the other end portion of the first direction, and a third memory mat positioned between the first and second memory mats;
a plurality of sense amplifier areas each arranged between two of the memory mats that are adjacent to each other in the first direction, each of the sense amplifier areas including a plurality of sense amplifiers;
first and second main amplifiers disposed such that the plurality of memory mats are sandwiched therebetween in the first direction; and
a plurality of first and second main input/output lines provided on the plurality of memory mats and extending in the first direction, wherein
each of the memory mats includes a plurality of bit lines extending in the first direction, a plurality of word lines extending in a second direction that crosses the first direction, and a plurality of memory cells disposed at intersections of the bit lines and word lines,
each of the sense amplifiers is connected to an associated one of the bit lines included in an adjacent one of the memory mats on one side of the first direction, and to an associated one of the bit lines included in an adjacent one of the memory mats on the other side of the first direction,
the first main input/output lines connect a plurality of sense amplifiers disposed between the first and third memory mats to the first main amplifier, and
the second main input/output lines connect a plurality of sense amplifiers disposed between the second and third memory mats to the second main amplifier.

12. The semiconductor device as claimed in claim 11, wherein neither the first input/output lines nor the second main input/output lines are disposed on the third memory mat.

13. The semiconductor device as claimed in claim 11, wherein
the first and third memory mats are both selected when a mat address indicates a first value, and
the second and third memory mats are both selected when the mat address indicates a second value that is different from the first value.

14. A semiconductor device comprising:
a plurality of memory arrays disposed in a first direction and a second direction that crosses the first direction;
a plurality of row decoders disposed along a first side of the memory arrays;
a plurality of first column decoders each disposed along a second side that does not face the first side of an associated one of the memory arrays; and
a plurality of second column decoders each disposed along a third side that faces the second side of an associated one of the memory arrays,
wherein each of the memory arrays is sandwiched between a corresponding one of the first column decoders and a corresponding one of the second column decoders.

15. The semiconductor device as claimed in claim 14, wherein each of the plurality of memory arrays includes a plurality of memory mats disposed in the first and second directions.

16. The semiconductor device as claimed in claim 14, further comprising a plurality of first and second column selection lines extend in the first direction formed on each of the memory arrays, wherein
the first column selection lines are connected to the first column decoders, and
the second column selection lines are connected to the second column decoders.

17. The semiconductor device as claimed in claim 15, wherein the plurality of memory mats includes a first end mat located adjacent to the first column decoder and a second end mat located adjacent to the second column decoder.

18. The semiconductor device as claimed in claim 17, wherein
the plurality of memory mats further includes a predetermined memory mat that is different from the first and second end mats,
the row decoder selects the first end mat and the predetermined memory mat when an address signal indicates a first value, and
the row decoder selects the second end mat and the predetermined memory mat when the address signal indicates a second value that is different from the first value.

19. The semiconductor device as claimed in claim 15, wherein the plurality of memory mats include first memory mats on which one of the first and second column selection lines passes, and second memory mats on which neither the first selection lines nor the second column selection lines pass.

20. The semiconductor device as claimed in claim 15, wherein
each of the memory mats includes a plurality of bit lines extending in the first direction, a plurality of word lines extending in the second direction, and a plurality of memory cells disposed at intersections of the bit lines and word lines,
the plurality of word lines are driven by a sub-word driver connected to a main word line that is driven by the row decoder, and
the plurality of bit lines are selectively connected to a main input/output lines by first and second column selection lines respectively driven by the first and second column decoders.
